(19) United States
(12) Patent Application Publication
(10) Pub. No.: US 2008/0128821 A1
(43) Pub. Date: Jun. 5, 2008

(54) Semiconductor Device Manufactured Using Passivation of Crystal Domain Interfaces in Hybrid Orientation Technology

(75) Inventors: Angelo Pinto, Allen, TX (US); P.R. Chidambaram, Richardson, TX (US); Srinivasan Chakravarthi, Murphy, TX (US); Rick L. Wise, Fairview, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/566,263

(22) Filed: Dec. 4, 2006

(51) Int. Cl. H01L 29/04; H01L 21/8238

(52) U.S. Cl. 257/369; 438/198; 257/E29.004; 257/E21.632

(57) ABSTRACT

The invention provides, in one aspect, a method of forming a semiconductor device including providing a semiconductor substrate that comprises a first portion having a crystal orientation and a second portion located over the first portion and having a different crystal orientation. An interfacial region is located between the first portion and second portion. A passivating dopant is implanted into the interfacial region to passivate unterminated bonds within the interfacial region.

### TECHNICAL FIELD OF THE INVENTION

The invention is directed, in general, to semiconductor devices and, more specifically, to semiconductor devices fabricated using passivation of unterminated bonds in an interfacial region associated with regions of different crystal orientation.

### BACKGROUND OF THE INVENTION

As the semiconductor industry continues to increase performance of integrated circuit devices in accordance with Moore's Law, physical limits of feature size are presenting new challenges to further improvement. For example, transistor gate lengths are approaching a value below which quantum effects cannot be neglected. Without new strategies, such challenges threaten to slow the rate of increase in device performance.

One such strategy involves increasing the mobility of minority charge carriers in a transistor so that the switching speed of the transistor may be increased without reducing the channel length of the transistor. A promising emerging technology dubbed “Hybrid Orientation Technology,” or HOT, involves producing localized, or “locally oriented” domains of crystal orientation on a semiconductor substrate. HOT relies on the principle that n-MOS transistors may operate faster on one orientation of a substrate, such as (100), while p-MOS transistors may operate faster on a different orientation, such as (110).

While some transistors formed on a HOT substrate may operate faster than they otherwise would, some device characteristics may be degraded. For example, some transistors formed in locally-oriented domains have been shown to exhibit higher leakage current from source/drain regions to the bulk substrate. Moreover, body contact from the transistors to the handle wafer may be non-ohmic. These effects may result in increase power dissipation and inadequate grounding of the integrated circuit.

Accordingly, what is needed in the art is a method of manufacturing transistors on a HOT substrate that reduces source/drain leakage and improves conduction across the interface between locally-oriented domains and the substrate.

### SUMMARY OF THE INVENTION

To address the above-discussed deficiencies of the prior art, the invention provides in one embodiment a method of forming a semiconductor device. The method includes providing a semiconductor substrate including a bulk portion having a first crystal orientation, a top layer having a second different crystal orientation, and an interfacial region between the bulk portion and the top layer. Silicon or germanium is implanted into the top layer to form an amorphous portion. The amorphous portion is annealed to produce a recrystallized portion having the first crystal orientation. A passivating dopant is implanted into the interfacial region to passivate unterminated bonds within the interfacial region, thereby forming a passivated portion. A MOS transistor of a first type is formed at least partially in the recrystallized portion and a MOS transistor of a second type different from the first type is formed at least partially in the top layer.

Another embodiment is a method of forming a semiconductor device. The method includes providing a semiconductor substrate having a first portion and a second portion. The first portion has a crystal orientation, and the second portion is located over the first portion and has a different crystal orientation. An interfacial region is located between the first portion and second portion. A passivating dopant is implanted into the interfacial region to passivate unterminated bonds within the interfacial region.

Another embodiment is a semiconductor device. The semiconductor device has a first substrate with a crystal orientation, and a second substrate with a different crystal orientation located over the first substrate. An interfacial region exists between the first and second substrates. A passivating dopant is located within the interfacial region that passivates one or more unterminated bonds. A MOS transistor of a first type is located at least partially in the first substrate, and a MOS transistor of a second different type is located at least partially in the second substrate.

### BRIEF DESCRIPTION OF THE DRAWINGS

For a more complete understanding of the invention, reference is now made to the following descriptions taken in conjunction with the accompanying drawings, in which:

FIGS. 1A, 1D and 1F are sectional views of an embodiment of a semiconductor device formed according to the invention;

FIGS. 1B and 1C illustrate lattice mismatch and passivation of unterminated bonds;

FIG. 1E illustrates a distribution of a passivating dopant;

FIGS. 2A-2C are sectional views of an alternate embodiment of a semiconductor device formed according to the invention; and

FIG. 3 is a sectional view of an integrated circuit.

### DETAILED DESCRIPTION

The invention recognizes that undesirable transistor characteristics associated with an interface between different crystal orientations of a hybrid-crystal orientation technology (HOT) substrate may be reduced by passivating unterminated bonds associated with lattice mismatch at the interface. Passivation may be accomplished, e.g., by implanting a passivating dopant that bonds to the unterminated bonds.

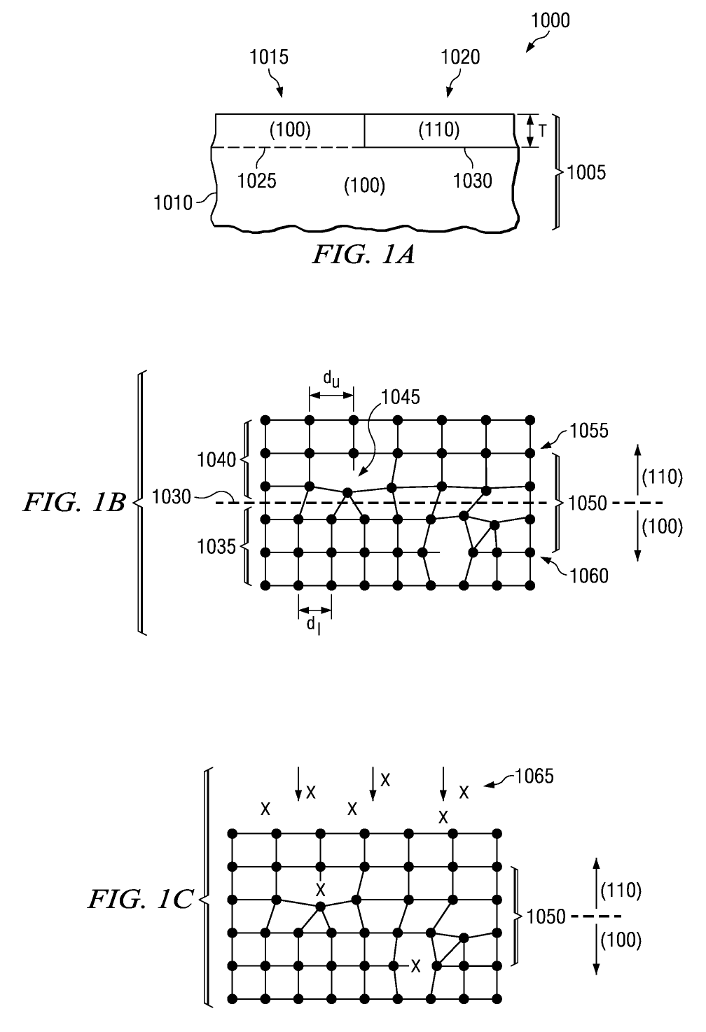

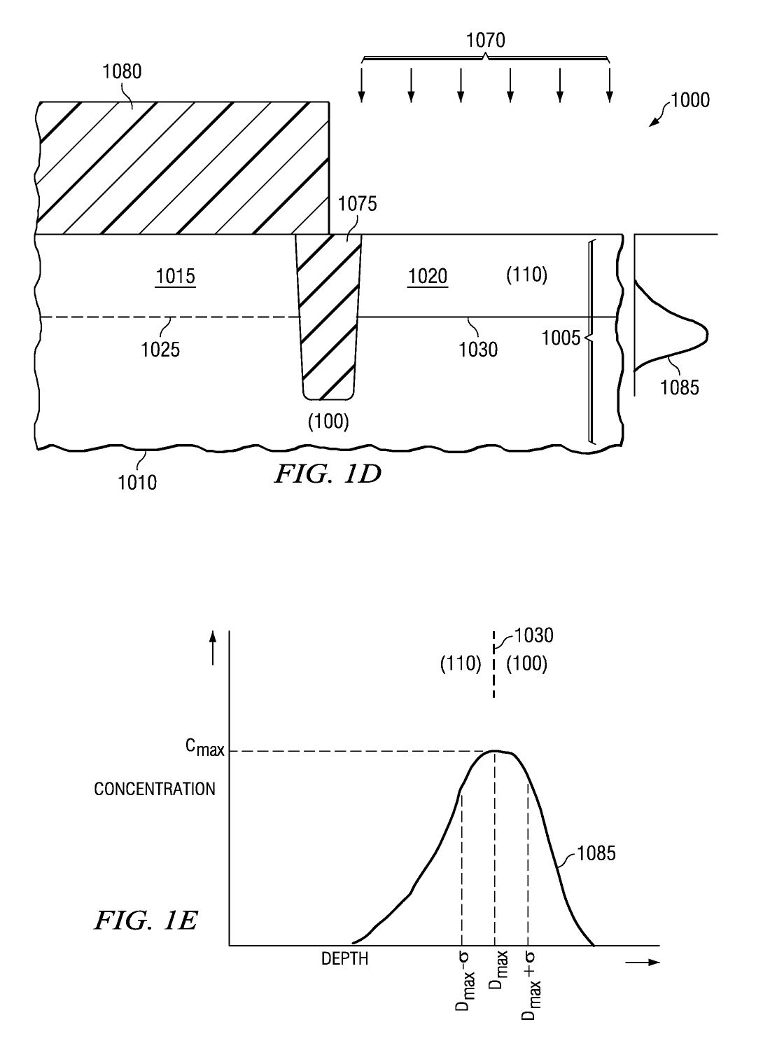

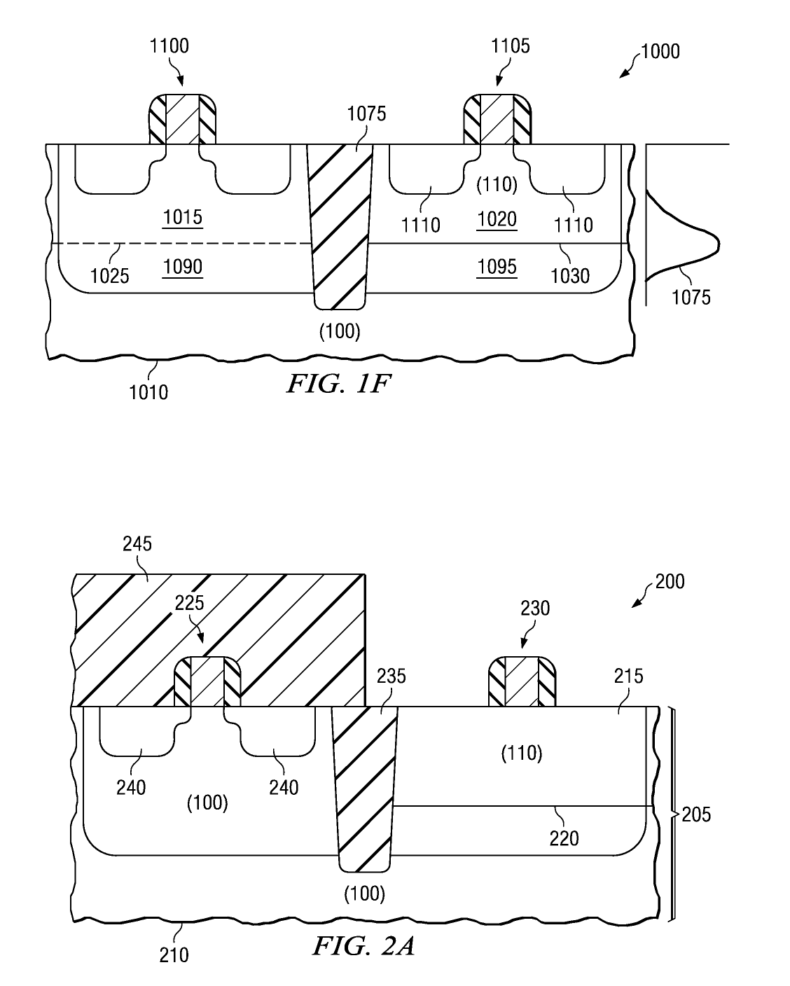

FIG. 1A illustrates a semiconductor device 1000 formed according to the invention. It is initially noted that, unless otherwise discussed, conventional processes and materials may be used to fabricate certain portions of the devices regarding the various embodiments discussed herein. The semiconductor device 1000 includes a HOT substrate 1005 that further includes a bulk portion 1010, an epitaxial portion 1015 and a hybrid portion 1020 with a thickness T. The epitaxial portion 1015 is substantially an extension of the lattice of the bulk portion 1010. Thus, the illustrated boundary 1025 between the bulk portion 1010 and the epitaxial portion 1015 is for illustration only, and may not reflect a significant physical discontinuity. However, the hybrid portion 1020 has a different crystal orientation from the bulk portion 1010, and thus, as discussed below, there is an interface 1030 therebetween.

A HOT substrate typically includes a “handle wafer,” having one crystal orientation, and a “crystal-oriented” top layer having a different crystal orientation from the handle wafer. The bulk portion 1010 may be a handle wafer. Those skilled in the art appreciate that the crystal orientation of a wafer describes the crystalline face presented at the surface of the wafer. For example, a (100) silicon wafer presents the (100) face of the silicon lattice at the surface, while a (110) silicon wafer presents a (110) face of the lattice at the surface.

The crystal-oriented layer may be formed by a bonding technique such as direct silicon bond (DSB). Locally oriented domains may be formed in the top layer by causing selected portions of the crystal-oriented layer to become amorphous, i.e., lacking long-range crystalline ordering. For example, portions of the crystal-oriented layer may be masked, and unmasked portions may be made amorphous by implanting silicon or germanium. The amorphous portions may then be recrystallized by solid-phase epitaxy (SPE) using the handle wafer as a lattice template. Alternatively, selected portions of the crystal-oriented layer may be removed and replaced by a portion having the crystal orientation of the handle wafer by gas-phase epitaxy. In either case, the unaltered portions of the crystal-oriented layer are regarded as locally-oriented domains.

A HOT substrate may be obtained from a supplying source or formed conventionally. As used herein, the HOT substrate 1005 is “provided” when obtained from any source or formed by any currently existing or future discovered method. For brevity, the following discussion assumes that the HOT substrate is a silicon substrate, while recognizing that other semiconductors such as germanium may be used.

Without limitation, FIG. 1A illustrates the case in which the hybrid portion 1020 is oriented (110) and the epitaxial portion 1015 is oriented (100). The epitaxial portion 1015 has the same crystal orientation as the bulk portion 1010. The epitaxial portion 1015 may have been formed, e.g., by selective epitaxial growth using the bulk portion 1010 as a lattice template. Other combinations of crystal orientation, such as the epitaxial portion 1015 oriented (110) and the hybrid portion 1020 oriented (100), e.g., are explicitly contemplated.

FIG. 1B illustrates, without limitation by theory, a view of the interface 1030 at an atomic level. A lower lattice 1035 below the interface 1030 and oriented (100), e.g., corresponds to the bulk portion 1010. An upper lattice 1040 above the interface 1030 and oriented (110), e.g., corresponds to the hybrid portion 1020. Because the lower lattice 1035 and the upper lattice 1040 have a different crystal orientation, in general a discontinuity results therebetween. In the illustrated embodiment, the lower lattice 1035 may be characterized by an atomic spacing dₗ, and the upper lattice may be characterized by an atomic spacing dᵤ, larger than dₗ. The difference between dₗ and dᵤ, results in lattice strain and unterminated, or “dangling,” bonds 1045. An unterminated bond represents an unfilled or partially filled atomic orbital that may accept an electron from another atom to form a bond therebetween.

The interface 1030 may be described by a plane between the lower lattice 1035 and the upper lattice 1040. However, the unterminated bonds are believed to diffuse several monolayers into the lower lattice 1035 and the upper lattice 1040 to reduce the energy of the lattice associated with strain. The portions of the lower and upper lattices 1035, 1040 that include unterminated bonds due to the lattice mismatch define an interfacial region 1050. In one embodiment, the location of the interface 1030 may be approximated as about midway between uppermost 1055 and lowermost 1060 atomic planes that experience deformation as a result of the lattice strain.

The unterminated bonds may trap charge carriers to produce a space-charge layer associated with the interfacial region 1050. As a result, I/V characteristics measured across the interface 1030 may display a non-ohmic conduction response. The non-ohmic response may interfere with good body contact in MOS devices. The space-charge layer may also result in increased leakage between the bulk portion 1010 and source/drain regions of MOS devices fabricated in the hybrid portions 1020.

These undesirable characteristics may advantageously be reduced by providing a chemical species to bond to the unterminated bonds 1045. When terminated, the bonds will typically not act as charge traps, conduction across the interface may be more ohmic, and associated transistor leakage may be reduced.

FIG. 1C, again without limitation by theory, illustrates at an atomic scale an implantation process 1065 configured to implant a passivating dopant generally denoted “x” into the interfacial region 1050. Some of the passivating dopant “x” is thought to combine with the unterminated bonds, thereby filling atomic orbitals associated with the unterminated bonds 1045 and rendering the bonds unavailable to trap charge. The bonds within the interfacial region 1050 that include the bonded passivating dopant are collectively referred to herein as a passivated portion.

FIG. 1D illustrates, at a device scale, an implantation process 1070 configured to implant a passivating dopant into the interfacial region 1050. An isolation structure 1075 has been formed between the epitaxial portion 1015 and the hybrid portion 1020. A masking layer 1080, such as a resist layer, may be used to restrict implantation of the passivating dopant to the hybrid portion 1020.

The passivating dopant is an atomic species extrinsic to the HOT substrate 1005 that, when implanted into a region containing an initial concentration of unterminated bonds, results in a decrease in the concentration of unterminated bonds. In one aspect, the passivating dopant may be a monovalent atomic species capable of forming a bond with the substrate atoms that is stable under ordinary operating conditions. Without limitation, hydrogen and fluorine are examples of such dopants. In some cases, a polyvalent atomic species may be used when that species may passivate multiple unterminated bonds, or when unterminated bonds associated with the polyvalent species may be in turn be passivated by another atomic species. For example, nitrogen may be used to passivate silicon unterminated bonds.

The implantation process 1070 may be performed using a semiconductor ion implantation tool. In some cases, the process may be designed to place a peak concentration of the passivating dopant within the interfacial region 1050. A dopant profile 1085 illustrates one position of the implanted dopant relative to the interface 1030.

By “within the interfacial region” it is meant that the interface 1030 is located within one standard deviation, σ, of a maximum concentration of the passivating dopant in the HOT substrate 1005. For example, FIG. 1E illustrates a case in which the interface 1030 is located between a depth of the maximum concentration of the passivating dopant, Dₘₐₓ, and Dₘₐₓ+σ. A peak concentration, Cₘₐₓ, is located in the (110) portion of the HOT substrate 1005. Because the interface 1030 is between Dₘₐₓ and Dₘₐₓ+σ, the peak concentration of the passivating dopant is within the interfacial region 1050.

Specific conditions for implanting the passivating dopant are expected to depend on, e.g., the thickness T and crystal orientation of the hybrid portion 1020. Without limitation, the following example assumes the hybrid portion 1020 is (110) silicon with a thickness of about 150 nm. Fluorine may be implanted normal to the surface at an energy of about 53 keV and a surface dose of about 10¹⁴ cm⁻². This implant is expected to produce a peak concentration of about 8·10¹⁸ cm⁻³ fluorine atoms about 150 nm below the surface of the HOT substrate 1005.

After implantation, the masking layer 1080 may be removed. In some embodiments, an anneal step may be performed to reduce lattice damage caused by the implantation, or to promote bonding of the passivating dopant to the unterminated bonds. If used, an anneal at a temperature ranging from about 950° C. and about 1025° C. for a period ranging from about 10 sec to about 30 sec is sufficient for these purposes. In other cases, an anneal after implanting the passivating dopant may be omitted, and an anneal associated with a later implantation process (source/drain, e.g.) may serve the purposes of the omitted anneal.

FIG. 1F illustrates the semiconductor device 1000 after formation of p- and n-wells 1090, 1095, an n-MOS transistor 1100 and a p-MOS transistor 1105. The transistors 1100, 1105 may be formed by a currently existing or future-discovered process. In this embodiment, the interface 1030 is located at least partially between space-charge layers associated with the n-well 1095 and source/drain regions 1110. Moreover, the interface 1030 is located outside the source/drain regions 1110 to reduce risk of migration of source/drain dopants along the interface 1030.

Advantageously, implantation of the passivating dopant may reduce leakage from p-MOS source/drain regions 1110 relative to the leakage present when the unterminated bonds in the interfacial region 1050 are not passivated. To illustrate, the example fluorine implant process recited above may result in a decrease of the reverse-bias leakage current of the source/drain regions 1110 of the p-MOS transistor 1105 to the n-well 1095 by about one order of magnitude or more.

In another embodiment, not shown, the passivating dopant may be implanted prior to formation of the isolation structure 1075. This ordering may be desirable to exploit efficiencies in a particular fabrication environment. If ordered in this manner, a similar benefit may be obtained as described above.

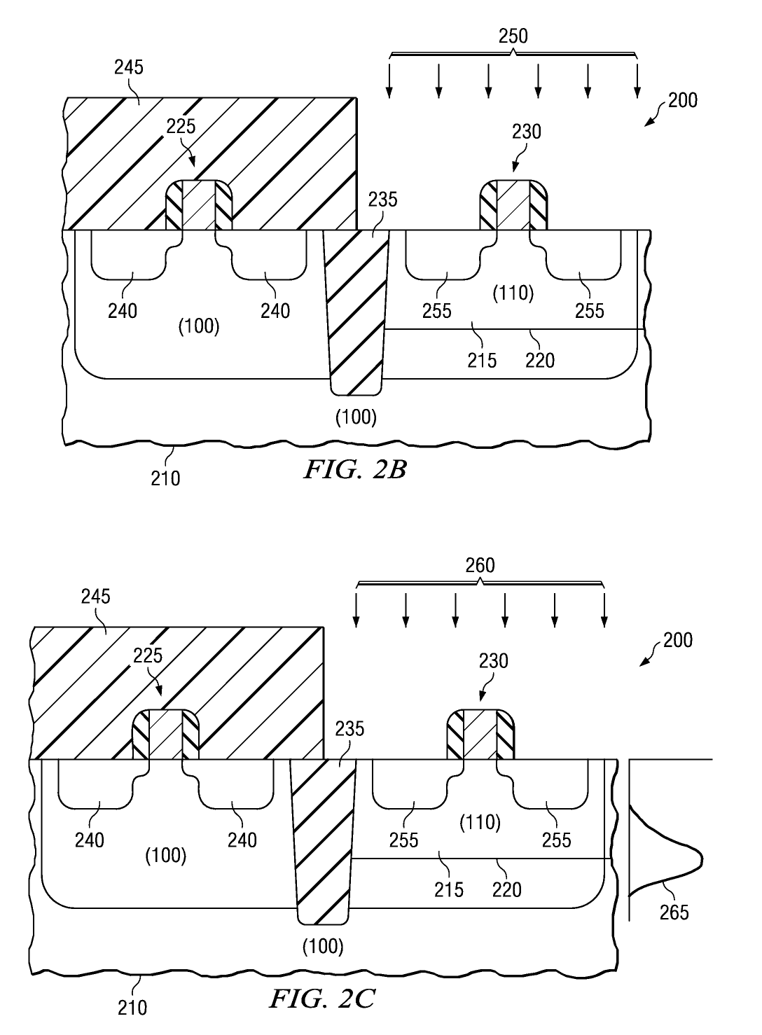

FIGS. 2A-2C illustrate another alternate embodiment, in which unterminated bonds associated with an interface between different crystal orientations of a HOT substrate are passivated after formation of MOS transistors. In FIG. 2A, a semiconductor device 200 is illustrated on a substrate 205 that includes a handle wafer 210 and a hybrid portion 215. The handle wafer 210 and the hybrid portion 215 form an interfacial region 220 that has unterminated bonds associated therewith. Well implants and gate structures of an n-MOS transistor 225 and a p-MOS transistor 230 have been formed prior to the illustrated step, and an isolation structure 235 has been formed therebetween. Source/drain regions 240 of the n-MOS transistor 225 has been formed, and a mask layer 245 has been placed thereover to block implantation of the passivating dopant into the n-MOS transistor 225.

In FIG. 2B, a source/drain formation process 250 may be used to produce source/drain structures 255 of the p-MOS transistor 230. The source/drain formation may comprise multiple implant steps and one or more anneal steps after each implant step.

In FIG. 2C, an implant process 260 is used to implant the passivating dopant into the interfacial region 220 through the source/drain regions 255. The implant process 260 may include implantation parameters similar to those recited previously. Such parameters may result in a passivation dopant profile 265 that has a peak concentration within an interfacial region associated with the interfacial region 220. As before, the implant process 260 may be followed by an anneal step. The anneal step may be the same anneal used to reduce lattice damage after implanting source/drain dopants, or may be in addition to the source/drain anneal. If the passivation dopant anneal is performed with the source/drain anneal, anneal parameters that take into account the presence of the source/drain dopants may need to be determined. In general, parameters of a combined anneal will depend on the process sequence used to fabricate specific devices.

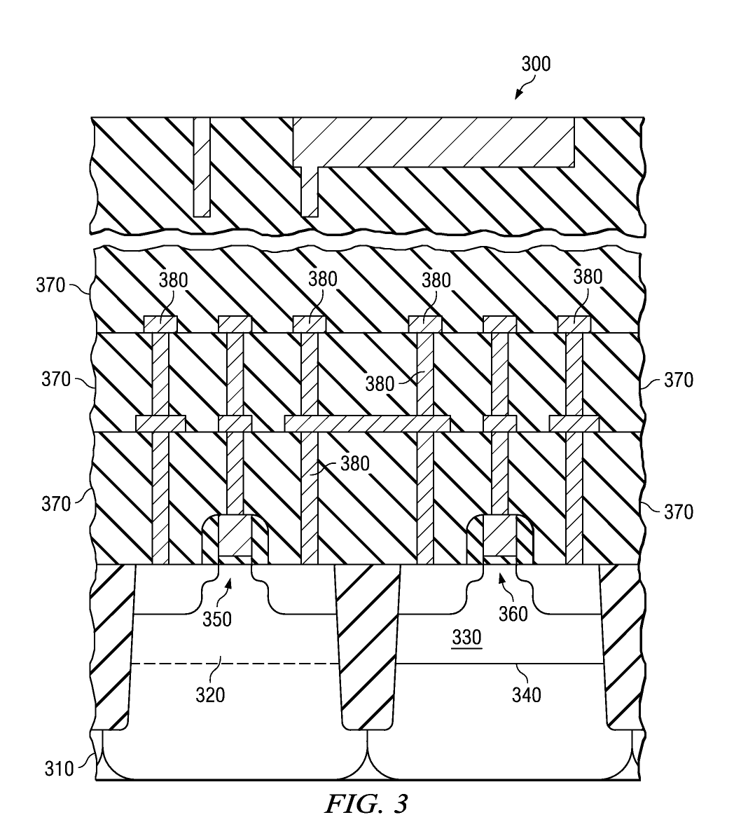

FIG. 3 illustrates an integrated circuit (IC) 300 formed according to the invention. The IC 300 is formed over a substrate 310 having an epitaxial portion 320 and a hybrid portion 330. The epitaxial portion 320 and the hybrid portion 330 have different crystal orientations in the manner described previously. A passivating dopant within an interfacial region 340 passivates unterminated bonds therein. A MOS transistor 350 of a first type is formed at least partially in the epitaxial portion 320, and a MOS transistor 360 of a second type is formed at least partially in the hybrid portion 330.

The IC 300 may include MOS, BICMOS or bipolar components, and may further include passive components, such as capacitors, inductors or resistors. It may also include optical components or optoelectronic components. Those skilled in the art are familiar with these various types of components and their manufacture. The IC 300 may also be a dual-voltage IC, comprising transistors operating with difference threshold voltages.

Dielectric layers 370 are formed over the MOS transistors 350, 360, using currently known or later discovered methods. Interconnect structures 380 are located within the dielectric layers 370 to connect the various components, thus forming the integrated circuit 300. It will be apparent to one skilled in the art that several variations of the example interconnect architecture may be fabricated according to the invention with similarly advantageous results.

Those skilled in the art to which the invention relates will appreciate that other and further additions, deletions, substitutions and modifications may be made to the described embodiments without departing from the scope of the invention.

What is claimed is:

1. A method of forming a semiconductor device, comprising;
providing a semiconductor substrate comprising a bulk portion having a first crystal orientation, a top layer having a second different crystal orientation, and an interfacial region between said bulk portion and said top layer;
implanting silicon or germanium into a portion of said top layer to form an amorphous portion;
annealing said amorphous portion to produce a recrystallized portion having said first crystal orientation;
implanting a passivating dopant into said interfacial region to passivate unterminated bonds within said interfacial region, thereby forming a passivated portion; and
forming a MOS transistor of a first type at least partially in said recrystallized portion and a MOS transistor of a second type different from said first type at least partially in said top layer.

2. The method as recited in claim 1, wherein said passivating dopant is hydrogen or fluorine.

3. The method as recited in claim 1, wherein said passivating dopant is nitrogen.

4. The method as recited in claim 1, wherein said first crystal orientation is (100) and said second crystal orientation is (110).

5. The method as recited in claim 1, wherein said MOS transistor of a first type is an n-MOS transistor, and said MOS transistor of second type is a p-MOS transistor.

6. A method of forming a semiconductor device, comprising;
providing a semiconductor substrate, wherein said semiconductor substrate comprises a first portion having a crystal orientation, a second portion located over said first portion and having a different crystal orientation, and an interfacial region located between said first portion and second portion;
implanting a passivating dopant into said interfacial region to passivate unterminated bonds within said interfacial region.

7. The method as recited in claim 6, wherein a peak concentration of said passivating dopant is located within said interfacial region.

8. The method as recited in claim 6, wherein said passivating dopant is fluorine or hydrogen.

9. The method as recited in claim 6, further comprising forming a transistor of a first type at least partially in said first portion, and forming a transistor of a second different type at least partially in said second portion.

10. The method as recited in claim 9, wherein said crystal orientation of said first portion is (100) and said different crystal orientation of said second portion is (110).

11. The method as recited in claim 10, wherein said first transistor type is n-MOS and said second transistor type is p-MOS.

12. The method as recited in claim 9, wherein said crystal orientation of said first portion is (110) and said different crystal orientation of said second portion is (100), and said first transistor type is p-MOS and said second transistor type is n-MOS.

13. The method as recited in claim 6, further comprising implanting said passivating dopant through source/drain regions formed in said second portion.

14. The method as recited in claim 6, wherein said passivating dopant is implanted into said interfacial region after formation of isolation structures in said substrate.

15. A semiconductor device, comprising:
a first substrate having a crystal orientation;
a second substrate having a different crystal orientation located over said first substrate, wherein an interfacial region exists between said first and second substrates;
a passivating dopant located within said interfacial region;
a MOS transistor of a first type located at least partially in said first substrate;
a MOS transistor of a second different type located at least partially in said second substrate.

16. The semiconductor device recited in claim 15, wherein said crystal orientation is (100) and said different crystal orientation is (110).

17. The semiconductor device recited in claim 16, wherein said first transistor type is n-MOS and said second transistor type is p-MOS.

18. The semiconductor device recited in claim 15, wherein said passivating dopant is hydrogen or fluorine.

19. The semiconductor device recited in claim 15, wherein said passivating dopant is nitrogen.

20. The semiconductor device recited in claim 15, wherein a peak concentration of said passivating dopant is within said interfacial region.
